(19) United States
(12) Patent Application Publication
(10) Pub. No.: US 2025/0100099 A1
(43) Pub. Date: Mar. 27, 2025

(54) CHEMICAL MECHANICAL POLISHING PAD

(71) Applicant: DuPont Electronic Materials Holding, Inc., Newark, DE (US)

(72) Inventors: Fengji YEH, Wilmington, DE (US); Bainian QIAN, Newark, DE (US)

(21) Appl. No.: 18/373,660

(22) Filed: Sep. 27, 2023

(51) Int. Cl. B24B 37/24

(52) U.S. Cl. CPC B24B 37/24

(57) ABSTRACT

A chemical mechanical polishing pad includes a polishing layer. The polishing layer comprises a matrix polymer and 1 to 20 wt % based on total weight of the polishing layer of non-reactive, non-expandable polymeric particles dispersed in the matrix polymer and less than 2 wt % expandable polymeric microspheres. An SEM of a cut surface of the polishing layer shows a crescent shaped opening adjacent to at least a portion of the polymer particles and separating a surface of that portion of the polymer particles from the matrix polymer.

### FIELD OF THE INVENTION

This invention relates to a polishing pad for chemical mechanical polishing.

### BACKGROUND OF THE INVENTION

In the fabrication of integrated circuits and other electronic devices, multiple layers of conducting, semiconducting and dielectric materials are deposited onto and removed from a surface of a semiconductor wafer. Thin layers of conducting, semiconducting and dielectric materials may be deposited using a number of deposition techniques. Common deposition techniques in modern wafer processing include physical vapor deposition (PVD), also known as sputtering, chemical vapor deposition (CVD), plasma-enhanced chemical vapor deposition (PECVD) and electrochemical plating, among others. Common removal techniques include wet and dry isotropic and anisotropic etching, among others.

As layers of materials are sequentially deposited and removed, the uppermost surface of the wafer becomes non-planar. Because subsequent semiconductor processing (e.g., metallization) requires the wafer to have a flat surface, the wafer needs to be planarized. Planarization is useful for removing undesired surface topography and surface defects, such as rough surfaces, agglomerated materials, crystal lattice damage, scratches and contaminated layers or materials.

Chemical mechanical planarization, or chemical mechanical polishing (CMP), is a common technique used to planarize or polish work pieces such as semiconductor wafers. In conventional CMP, a wafer carrier, or polishing head, is mounted on a carrier assembly. The polishing head holds the wafer and positions the wafer in contact with a polishing layer of a polishing pad that is mounted on a table or platen within a CMP apparatus. The carrier assembly provides a controllable pressure between the wafer and polishing pad. Simultaneously, a polishing medium (e.g., polishing solution or slurry) is dispensed onto the polishing pad and is drawn into the gap between the wafer and polishing layer. For purposes of this application, polishing solution means polishing solution with or without particles and polishing slurry means polishing solution with particles. To effect polishing, the polishing pad and wafer typically rotate relative to one another. As the polishing pad rotates beneath the wafer, the wafer sweeps out a typically annular polishing track, or polishing region, wherein the wafer's surface directly confronts the polishing layer. The wafer surface is polished and made planar by chemical and mechanical action of the polishing layer and polishing medium on the surface.

Chemical mechanical polishing pads often include grooves cut into the polishing surface. These grooves are considered macrotexture and can enhance performance of the pad. For example, the grooves can facilitate removal of debris from the polishing surface that could scratch the surface. In addition, polishing pads can include microtexture. See, e.g., U.S. Pat. No. 5,489,233 describing a pad having macrotexture and microtexture.

In some instances, the polishing layer can be porous—e.g., through inclusion of expandable polymeric microspheres. The porosity can provide microtexture to a polishing surface of a pad. As the pad is conditioned by an abrasive material during patterned wafer polishing, wear of the polymer material exposes the pores to form microtexture. See FIG. 1.

However, porous pads can be less effective at planarization because the pad can conform too much to variations in elevation of the substrate being polished. For example, as shown in FIG. 2, a substrate 10 to be polished incudes elevated features 11. A porous polishing pad 20, having pores 21 in a matrix polymer 22 can deform under the pressure of polishing. In addition, porous pads can lead to dishing in the substrate.

Unfilled, non-porous pads can provide an improvement in rigidity during polishing over porous pads, but with certain soft or ductile materials used in a polishing layer, it can be challenging to produce the pads through machining with the desired macrotexture. As shown in FIG. 3A there can be lack of uniformity in the grooves and spacing. Further, as shown in FIGS. 3A and 3B, there can be rough edges and debris.

It would be desirable to provide a pad that provided improved planarization capabilities over porous pads, which could also be more easily cut and machined to provide the desired macrotexture and microtexture.

### SUMMARY OF THE INVENTION

Disclosed herein is a chemical mechanical polishing pad having a polishing layer, wherein the polishing layer comprises a matrix polymer and 1 to 20 wt % based on total weight of the polishing layer of non-reactive, non-expandable polymeric particles dispersed in the matrix polymer and less than 2 wt % expandable polymeric microspheres, wherein an SEM of a cut surface of the polishing layer shows a crescent shaped opening adjacent to at least a portion of the polymer particles and separating a surface of that portion of the polymer particles from the matrix polymer.

### BRIEF DESCRIPTION OF THE DRAWINGS

Referring now to the figures, which are exemplary embodiments, and wherein the like elements are numbered alike.

FIG. 1 is a scanning electron microscope (SEM) photo at 200× magnification showing a surface of a porous polishing pad having expanded polymeric microspheres after polishing.

FIG. 2 is a cross-sectional schematic of a porous polishing pad polishing a substrate with elevated surface elements.

FIGS. 3A and 3B are photographs showing grooves on a surface of a comparative unfilled polishing pad.

FIG. 4 cross-sectional schematic of a polishing pad as disclosed herein polishing a substrate with elevated surface elements.

FIG. 5 is an SEM at 500× magnification of a cut surface of a polishing layer of a polishing pad as disclosed herein.

FIG. 6 is an SEM at 500× magnification of a cut surface of a polishing layer of a polishing pad as disclosed herein.

FIG. 7 is an SEM at 500× magnification of a cut surface of a prior art polishing pad having polishing layer with expanded polymeric microspheres to impart porosity.

FIG. 8 is an SEM at 500× of a post polish surface of a pad as disclosed herein.

FIG. 9 is an SEM of a post-polish surface of a pad comprising expandable polymeric microspheres.

FIGS. 10A and 10B are photographs showing grooves on a surface of a polishing pad as disclosed herein.

FIG. 11 is a photograph showing an attempted circular groove pattern on a pad according to Comparative Sample D.

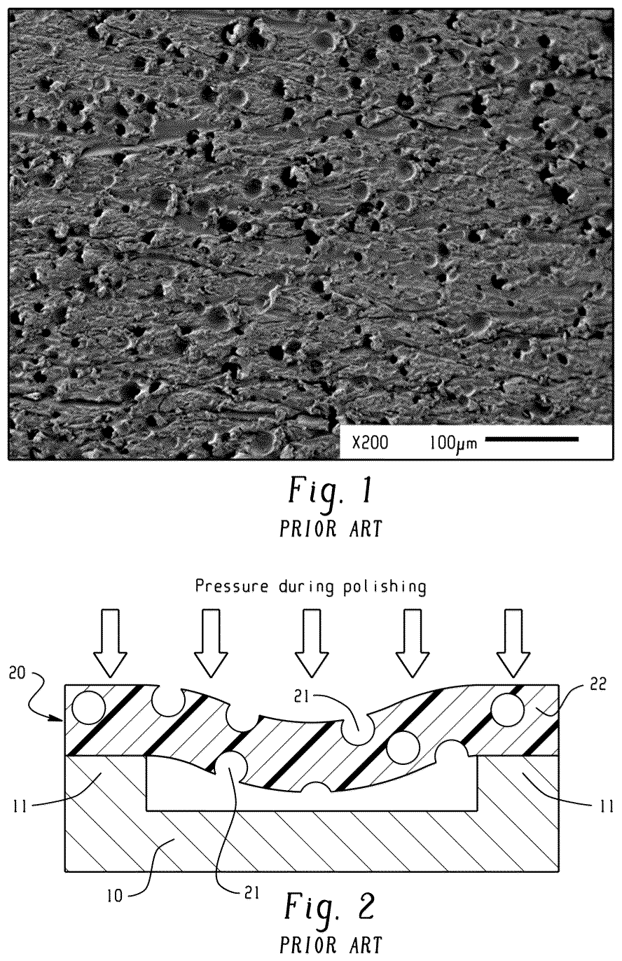

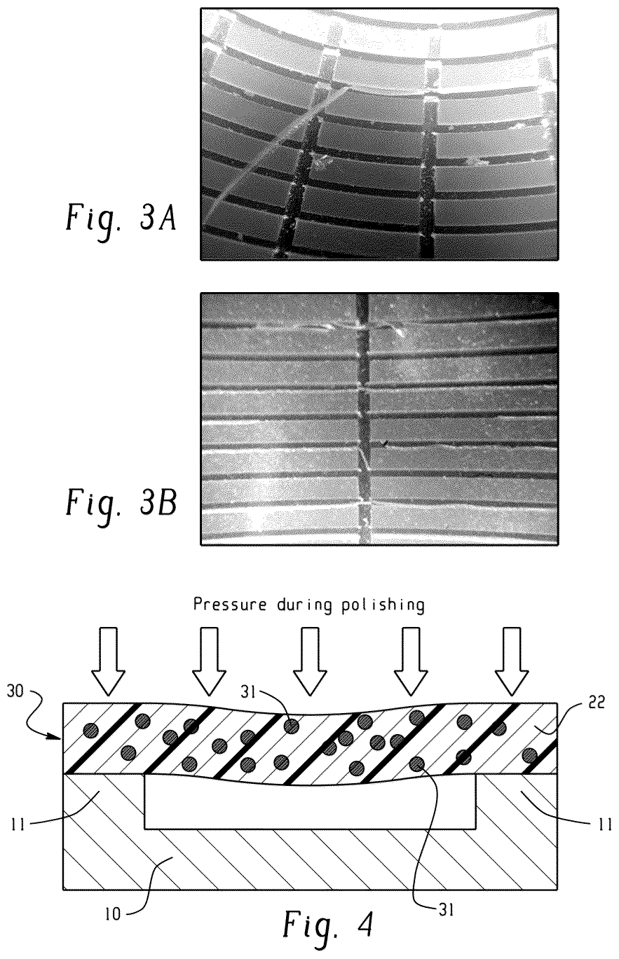

### DETAILED DESCRIPTION OF THE INVENTION

The polishing pads disclosed herein comprise particles in a matrix polymer.

The matrix polymer can be a polyurethane. The matrix polymer can have a coefficient of thermal expansion (CTE) of greater than or equal to 140×10⁻⁶, or greater than or equal to 150×10⁻⁶ and up to 250×10⁻⁶, up to 200×10⁻⁶, up to 180×10⁻⁶, or up to 170×10⁻⁶ millimeters per millimeter of original length of the sample per degree C. (mm/mm-° C.) in a temperature range of 20° C. to 150° C. The matrix polymer can be ductile. The matrix polymer can have a surface energy of 36 milliJoules per square meter (mJ/m²) to 39 mJ/m² by contact angle with water and organic liquids at 20° C. The matrix polymer can have a Shore D hardness according to ASTM D2240-15 (2015) of 30 to 80, typically 50 to 80. The matrix polymer can exhibit a wet Shore D hardness of from 5 or from 10 up to 20% less than the (dry) Shore D hardness of the matrix polymer.

For example, the polyurethane can be a reaction product of a mixture comprising a curative, such as one or more polyamine or polyol curative, and a polyisocyanate prepolymer (or a blend of two or more polyisocyanate pre-polymers).

The polyisocyanate prepolymer can comprise a reaction product of ingredients, comprising: a polyfunctional isocyanate and a prepolymer polyol and optionally a low molecular weight polyol.

The polyfunctional isocyanate can be an aliphatic polyfunctional isocyanate, an aromatic polyfunctional, or a mixture thereof. The polyfunctional isocyanate can be a diisocyanate, for example, 2,4 toluene diisocyanate; 2,6 toluene diisocyanate; 2,2′ diphenylmethane diisocyanate; 2,4′ diphenylmethane diisocyanate; 4,4′ diphenylmethane diisocyanate; naphthalene 1,5 diisocyanate; tolidine diisocyanate; para phenylene diisocyanate; xylylene diisocyanate; isophorone diisocyanate; hexamethylene diisocyanate; 4,4′ dicyclohexylmethane diisocyanate; cyclohexane diisocyanate; or mixtures of two or more thereof. The polyfunctional isocyanate can be a toluene diisocyanate.

The prepolymer polyol can be selected from the group consisting of diols, polyols, polyol diols, copolymers thereof, and mixtures thereof. The prepolymer polyol can be selected from the group consisting of polyether polyols (e.g., poly(oxytetramethylene)glycol, poly(oxypropylene)glycol, poly(oxyethylene)glycol, poly(oxypropylene)-co-poly(oxyethylene) glycol); polycarbonate polyols; polyester polyols; polycaprolactone polyols; mixtures thereof. The prepolymer polyol can be, for example, polytetramethylene ether glycol (PTMEG); polypropylene ether glycols (PPG), polyethylene ether glycols (PEG), polyethylene ether glycol-co-polypropylene ether glycols (PEG-PPG copolymer), or mixtures of two or more thereof. For example, the prepolymer can be a blend of PPG and PTMEG in a weight ratio of PPG:PTMEG of from 1:20, or 1:15 up to 20:1, up to 10:1, up to 5:1, up to 1:1, or up to 1:10.

The low molecular weight polyol can be, for example, ethylene glycol; 1,2 propylene glycol; 1,3 propylene glycol; 1,2 butanediol; 1,3 butanediol; 2 methyl 1,3 propanediol; 1,4 butanediol; neopentyl glycol; 1,5 pentanediol; 3 methyl 1,5 pentanediol; 1,6 hexanediol; diethylene glycol; dipropylene glycol; or tripropylene glycol.

The polyisocyanate prepolymer can have an unreacted isocyanate (NCO) concentration of 7 to 11.4, 8 to 10, 8.3 to 9.8, 8.5 to 9.5, 8.6 to 9.3, 8.7 to 9.25, or 8.9 to 9.25 wt % based on total weight of the isocyanate terminated urethane prepolymer. Examples of commercially available isocyanate terminated urethane prepolymers include Imuthane® prepolymers (available from COIM USA, Inc., such as, PET 80A, PET 85A, PET 90A, PET 93A, PET 95A, PET 60D, PET 70D, PET 75D); Adiprene® prepolymers (available from LANXESS Urethane Systems, such as, LF 800A, LF 900A, LF 910A, LF 930A, LF 931A, LF 939A, LF 950A, LF 952A, LF 600D, LF 601D, LF 650D, LF 667, LF 700D, LF750D, LF751D, LF752D, LF753D and L325); Andur® prepolymers (available from Anderson Development Company, such as, 70APLF, 80APLF, 85APLF, 90APLF, 95APLF, 60DPLF, 70DPLF, 75DPLF).

The aromatic diisocyanate, such as toluene diisocyanate, can be present in the reaction mixture in amounts, of, for example, from 33 or from 35 up to 46 or up to 45 wt %, based on the total wt % of the reactants used to make the polyisocyanate prepolymer.

The optional low molecular weight polyol can be present in the reaction mixture in amounts of from 1 or from 3 up to 12 or up to 11 wt % based on the total weight of the reactants used to make the polyisocyanate prepolymer.

To form a polishing material a mixture is prepared comprising of reactants from 65, from 70, or from 75 up to 80, up to 79 or up to 78 wt % of the polyisocyanate prepolymer, and from 15, or from 20 up to 30, up to 27.5, or up to 25 wt % of the curative based on total weight of the mixture. The mixture also includes non-reactive, non-expandable polymeric beads in an amount of from 1, from 3, from 5, from 6, from 7, or from 8 up to 20, up to 15, up to 14, or up to 12 wt % based on total weight of the mixture. For purposes of this specification, expandable polymeric beads expand greater than 5% in diameter when heated to temperatures above their glass transition temperature and non-expandable polymeric beads expand less than 1% in volume when heated to temperatures above their glass transition temperature.

The stoichiometric ratio of the sum of the total moles of amine (NH2) groups and the total moles of hydroxyl (OH) groups in the curative mixture to the total moles of unreacted isocyanate (NCO) groups in the reaction mixture ranges from 0.85:1, or 0.91:1, or from 0.95:1 or from 0.98:1 up to 1.15:1, or up to 1.10:1, or up to 1.05:1. The polyurethane reaction product can be formed from a reaction mixture comprising the polyisocyanate prepolymer and the curative mixture wherein the molar ratio of polyamine NH2 groups to polyol OH groups ranges from 2:1 or 4:1 or 25:1 or 50:1 up to 1:0 or pure amine (wherein when the molar ratio is 1:0 there are no OH groups remaining in the curative mixture) or up to 70:1.

The polyisocyanate prepolymer can have a number average molecular weight (GPC) of, for example, from 500, or from 600 up to 2000, up to 1500, up to 1200, or up to 1000 grams per mol (g/mol).

The curative can be a polyamine, a polyol, or a mixture of a polyamine and a polyol. Examples of polyamine curatives include 4,4′-methylene-bis(3-chloro-2,6-diethylaniline) or 4,4′ methylene bis (2 chloroaniline); diethyl toluene diamines; tert-butyl toluene diamines, such as 5-tert-butyl-2,4- or 3-tert-butyl-2,6-toluenediamine; chlorotoluenediamines; dimethylthio-toluene diamines; 1,2-bis(2-aminophenylthio) ethane; trimethylene glycol di-p-amino-benzoate; tert-amyl toluenediamines, such as 5-tert-amyl-2,4- and 3-tert-amyl-2,6-toluenediamine; tetramethyleneoxide di-p-aminobenzoate; (poly) propyleneoxide di-p-aminobenzoates; chloro diaminobenzoates; methylene dianilines, such as 4,4′-methylene-bis-aniline; isophorone diamine; 1,2-diaminocyclohexane; bis(4-aminocyclohexyl) methane, 4,4′-diaminodiphenyl sulfone, m-phenylenediamine; xylene diamines; 1,3-bis(aminomethyl cyclohexane); and mixtures thereof. For example, the amine curative can be, 4,4′-methylene-bis-o-chloroaniline. Examples of polyol curatives include ethylene glycol; 1,2 propylene glycol; 1,3 propylene glycol; 1,2 butanediol; 1,3 butanediol; 2 methyl 1,3 propanediol; 1,4 butanediol; neopentyl glycol; 1,5 pentanediol; 3 methyl 1,5 pentanediol; 1,6 hexanediol; diethylene glycol; dipropylene glycol; or tripropylene glycol; Specflex® polyols, Voranol® polyols and Voralux® polyols (available from The Dow Chemical Company); Multranol® Specialty Polyols and Ultracel® Flexible Polyols (available from Covestro AG); and Pluracol® Polyols (available from BASF.

The mixture includes polymeric beads that do not react and do not substantially expand (i.e., are not considered expandable particles from entrapped gas or liquid) during the reaction and formation of the polishing material. The polymeric beads can be substantially non-porous or can contain some porosity. Pads having beads with some porosity can be more easily machined and conditioned. Beads without porosity can have a density of, for example, about 1.1 to 1.2, or 1.15 to 1.18, grams per cubic centimeter (g/cc) although density can vary depending on specific polymer selected. Beads including porosity can have density up to a value less than the density for the non-porous bead (e.g., less than 1.1, less than 1.15, or less than 1.18). For example, beads including porosity can have a density of from 0.75, or from 0.8 up to 1.1, up to 1.0 or up to 0.95 g/cc.

The polymeric beads can have, for example a coefficient of thermal expansion (CTE) of no greater than 120×10⁻⁶, for example from 70×10⁻⁶ up to 120×10⁻⁶ up to 100×10-6, or up to 90×10⁻⁶ millimeters per millimeter of original length of the sample per degree C. (mm/mm-° C.) in a temperature range of 20° C. to 150° C. The polymeric beads can have a surface energy of, for example, 40 mJ/m² to 43 mJ/m² at 20° C. derived via contact angle with water and various organic liquids. Without wishing to be bound by theory, a difference in CTE or surface energy between the matrix polymer and the beads may contribute to the unique properties and effectiveness of a polishing pad as disclosed herein. For example, the CTE of the polymeric beads can be at least 30, or at least 40 or at least 50 mm/mm° C. less than the CTE of the polyurethane matrix.

The polymeric beads can comprise, for example cross-linked (meth)acrylate polymers or non-crosslinked (meth)acrylate, polyolefins such as polyethylene, polypropylene or olefin copolymers, poly lactic acid (PLA), poly lactic-co-glycolic acid (PLGA), polysiloxanes, or cellulose polymers. Advantageously, the polymeric beads have a modulus greater than the polymer matrix. The higher modulus in combination with the lack of chemical bonds between the polymeric beads and the polymer matrix contributes to the release of the particles during conditioning of the polishing pad with an abrasive, such as a diamond abrasive.

The polymeric beads can have an average particle size, D50, as measured by particle size analyzer of less than 20 micrometers, for example greater than 2, at least 3, at least 6, at least 7, at least 8, at least 9 or at least 10 up to 20, up to 18, up to 15, up to 14, up to 13, or up to 12 micrometers. For purposes of this application, D50 represents the equivalent particle diameter of the 50th percentile by cumulative population. Equivalent particle diameter represents the size is equivalent to the diameter of a spherical particle with the same volume.

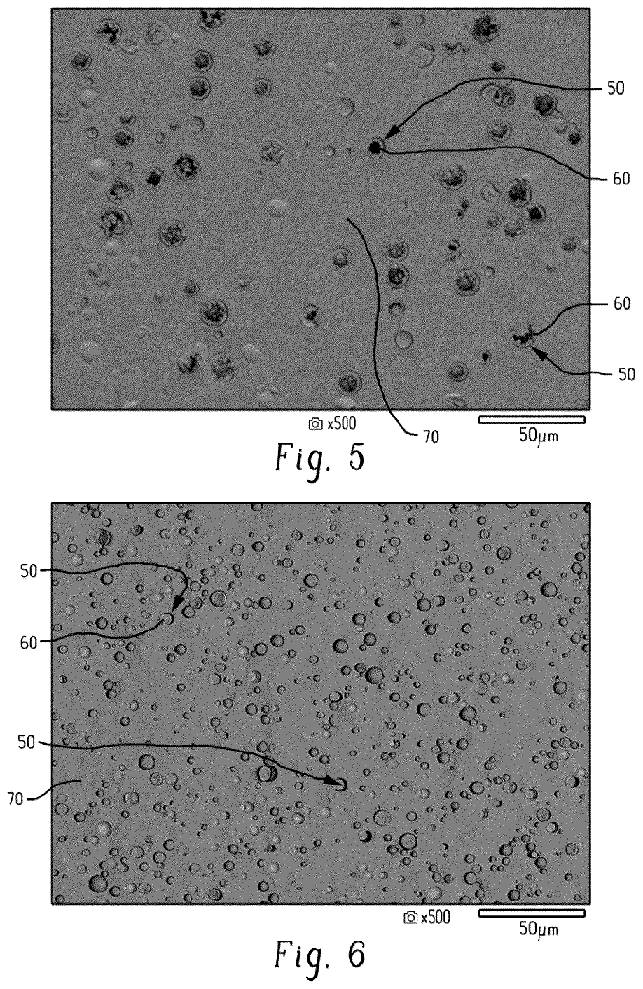

The polymeric beads can provide a unique morphology to the pads. For example, as shown in FIG. 5 and FIG. 6, a surface from a cut with a sharp implement reveals a crescent shaped gap 50 between a surface of the polymeric bead 60 and the polymer matrix 70. Referring to FIGS. 5 and 6, the crescent shape refers to the gap 50 formed between the polymeric bead 60 and the polymeric matrix 70 with an SEM at a magnification of at least 500× using a microtome blade with the microtome and polymer matrix at room temperature or 20° C. Typically, the microtome blade moves the polymeric beads 60 in the cutting direction moving the polymeric beads 60 against the polymeric matrix 70 wall at the opposite of the initial blade contact. Typical spacing between the polymeric beads 60 and the polymeric matrix 70 is at least 0.1 μm with a range of 0.1 μm to 7 μm as measured at polymeric beads 60 remaining in the polymeric matrix 70 after the microtome of polymeric beads 60 cut with a diameter of at least fifty percent of the average diameter. Most advantageously, this distance is 0.2 to 5 μm. Furthermore, this measurement is most advantageously for spherical polymeric beads 60 where the polymeric bead 60 is at or near contact with a side wall of the polymeric matrix 70 opposite the measured distance. This movement of the polymeric beads 60 during cutting with a microtome appears to result from the polymeric beads 60 having weak or no bonds securing the polymeric beads 60 to the polymeric matrix 70.

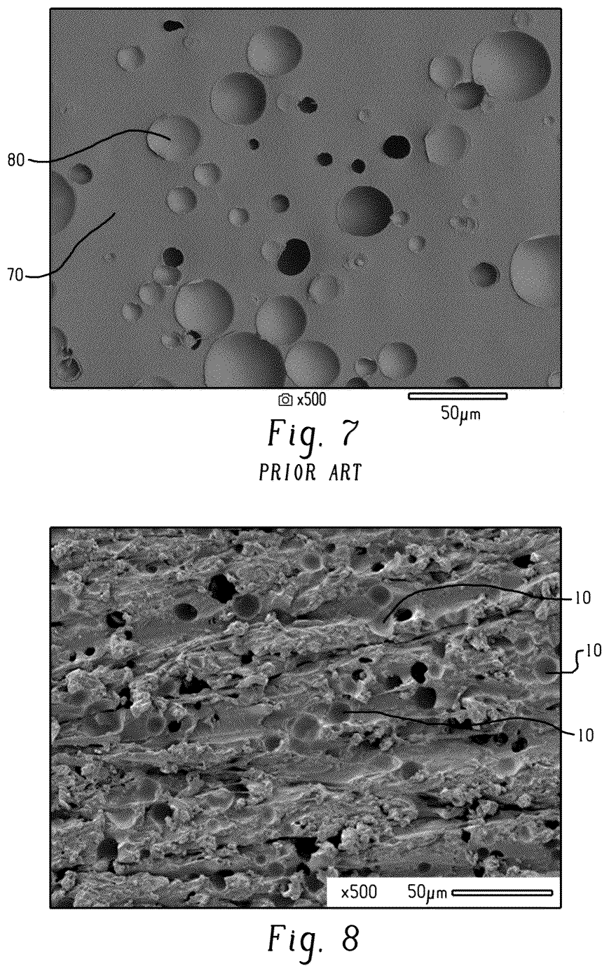

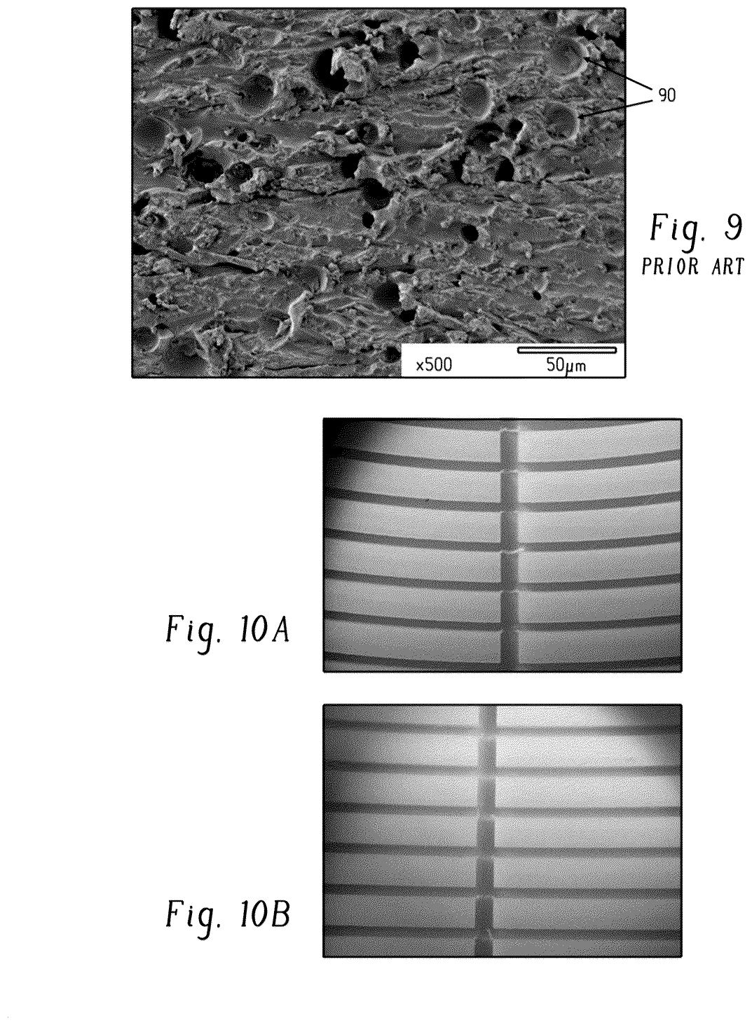

The beads in FIG. 5 were somewhat porous, while the beads in FIG. 6 are non-porous. In contrast, in FIG. 7 a cut surface of polishing material having the same polymer matrix material 70 as in the material shown in FIG. 5, but including expandable polymeric microspheres 80, shows a distinct morphology. Further, the polymeric beads are removed or released from the surface during conditioning, leaving depressions 10 in the surface that are hemispheric or the like as shown in FIG. 8. These depressions 10 are advantageously hemispherical shaped. Furthermore, the conditioning, such as diamond conditioning forms microscopic channels in the polymeric matrix. The hemispherical depressions and microscopic channels combine to form the microtexture of the polishing layer of the polishing pad. In contrast, a pad used with expandable polymeric microspheres also show depressions, but they often include the shell of the polymeric microsphere as shown in FIG. 9 where the residual shell 90 is visible.

Advantageously, the polishing pad includes less than 2 wt % expandable polymeric microspheres. Most advantageously, the polishing pad includes less than 1 wt % expandable polymeric microspheres. The mixture used in making the polishing material can be free of or substantially free of expandable polymeric microspheres. By substantially free is meant that the mixture contains less than 0.2, less than 0.1, less than 0.05 or less than 0.01 wt % of expandable polymeric microspheres based on total weight of the mixture. The mixture can include 0 or less than 0.1 wt % amount of polytetrafluoroethylene or other fluoropolymer particles having average diameter of 3-75 micrometers based on total weight of the mixture.

The polishing material can be formed by combining in a mixture under reaction conditions of the polyisocyanate prepolymer, the curative and the polymeric beads. For example, this may include providing a mold; pouring the mixture of the reactants and the polymeric beads into the mold; and, allowing the combination to react in the mold to form a cured cake, wherein the polishing layer is derived from the cured cake. For example, the mixture can be prepared by providing the polyisocyanate prepolymer of at a temperature of, for example, from 45 to 65° C., cooling the prepolymer to from 20 to 40° C., forming the reaction mixture of the polyisocyanate prepolymer, the curative, and the polymeric beads. Further, the method can include, preheating a mold to, for example, from 60 from 65 to 100 or to 95° C., filling the mold with the reaction mixture and heat curing the mixture at a temperature of from 80 to 120° C. for a period of from 4, or from 6 to 24 or to 16 hours to form a molded polyurethane reaction product. The cured cake is skived (cut) to derive multiple polishing layers from a single cured cake. The polishing layer so cut can have a thickness of from 0.5 or 1 mm up to 10, up to 5 or up to 3 mm. Optionally, the method further comprises heating the cured cake to facilitate the skiving operation. Optionally, the cured cake is heated using infrared heating lamps during the skiving operation in which the cured cake is skived into a plurality of polishing layers.

The polishing layer has a density of at least 1.08, or at least 1.10 grams/cubic centimeter. The polishing layer can have a density of up to 1.2, or 1.15 grams/cubic centimeter. Density can be determined by measuring the weight and volume of a sample and dividing the weight by the volume.

The polishing layer of the chemical mechanical polishing pad of the present invention exhibits a Shore D hardness of 55 to 75 as measured according to ASTM D2240-15 (2015). These hardness values were measured by stacking four 3.81 cm square samples having a thickness of 80 mils (2.032 mm) to eliminate error from measuring the support surface using a Hoto Instruments Asker P2 Durometer with a D probe. Polishing layers exhibiting a Shore D hardness of less than 40 typically have very high elongation to break values (i.e., >600%). Materials exhibiting such high elongation to break values irreversibly deform when subjected to machining operations, which results in groove formation that is unacceptably poor and texture creation during diamond conditioning that is insufficient. Preferably, the polishing layer of the chemical mechanical polishing pad of the present invention exhibits an elongation to break of from 100 to 450% or, preferably, from 125 to 425% (still more preferably 150 to 350%; most preferably 250 to 350%) as measured according to ASTM D412-06a (2006). The test used a MTS Criterion C43 tester with an Instron 2712-02 load cell of a maximum load at 1000 Newton and Instron pneumatic side action grips clamping at approximately 30 psi (207 kPa). The test specimens were based on the dimension of Standard Dumbbell Die C with US customary units with a thickness of 80 mils (2.032 mm) and the test temperature was at 23° C.+/−2° C. The specimens were deformed at 20 inches (50.8 cm)+/−2 inches per minute (5.08 cm/min) of the grips. Five replicates were measured for each sample and the median values were reported.

Preferably, the polishing layer used in the chemical mechanical polishing pad of the present invention has an average thickness of from 500 to 3750 microns (20 to 150 mils), or, more preferably, from 750 to 3150 microns (30 to 125 mils), or, still more preferably, from 1000 to 3000 microns (40 to 120 mils), or, most preferably, from 1250 to 2500 microns (50 to 100 mils).

The chemical mechanical polishing pad of the present invention optionally further comprises at least one additional layer interfaced with the polishing layer. Preferably, the chemical mechanical polishing pad optionally further comprises a compressible sub pad or base layer adhered to the polishing layer. The compressible base layer preferably improves conformance of the polishing layer to the surface of the substrate being polished.

The polishing layer of the chemical mechanical polishing pad of the present invention has a polishing surface adapted for polishing the substrate. The polishing surface has macrotexture. The macrotexture can be grooves, depressed features or elevated features. The macrotexture can have dimensions on the order of 10% to 60% of the polishing layer thickness in depth (e.g. 50 to 2250 microns) and 250 to 1270 microns (about 10 mil to 50 mil) in width. For example, the macrotexture can include at least one of perforations and grooves. Perforations can extend from the polishing surface part way or all the way through the thickness of the polishing layer. Grooves are arranged on the polishing surface such that upon rotation of the chemical mechanical polishing pad during polishing, at least one groove sweeps over the surface of the substrate being polished. For example, the polishing layer can have macrotexture including at least one groove selected from the group consisting of curved grooves, linear grooves, perforations and combinations thereof.

As a specific example the macrotexture can be a groove design comprising a plurality of grooves. The groove design can be concentric grooves (which may be circular or spiral), curved grooves, cross hatch grooves (e.g., arranged as an X-Y grid across the pad surface), other regular designs (e.g., hexagons, triangles), tire tread type patterns, irregular designs (e.g., fractal patterns), or combinations thereof. The groove profile is preferably selected from rectangular with straight side walls or the groove cross section may be “V” shaped, “U” shaped, saw-tooth, and combinations thereof.

The macrotexture (e.g. grooves) may be cut into the polishing surface of the polishing pad either using a lathe or by a CNC milling machine.

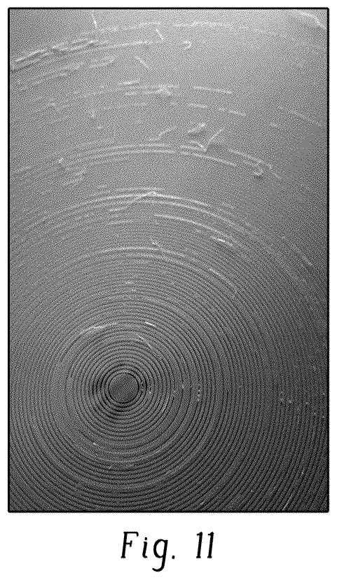

The polishing layer as disclosed herein can be readily machinable to provide macrotexture without defects. For example, as shown in FIGS. 10A and 10B, the walls of grooves machined into the surface of the polishing layer can be straight, or smooth curves without significant defects seen in the walls or in the grooves.

The chemical mechanical polishing pad as described herein can be used in polishing substrates. Particularly, the method comprises providing a substrate to be polished, providing a polishing pad as described herein. The polishing pad is initially conditioned before beginning polishing of the substrate with the polishing pad. In addition, the polishing pad can be further conditioned during intermittent breaks during the polishing process (ex situ). The intermittent breaks can be during polishing of a single substrate or between polishing of a first substrate and a second substrate. The conditioning can comprise the polishing surface mechanically, for example with a conditioning disk. The conditioning disk has a rough conditioning surface typically comprised of imbedded diamond points. The conditioning process cuts microscopic furrows into the pad surface, both abrading and plowing the pad material and renewing the polishing texture. The conditioning disk can be rotated in a position that is fixed with respect to the axis of rotation of the polishing pad and sweeps out an annular conditioning region as the polishing pad is rotated.

The substrate to be polished can be a magnetic substrate, an optical substrate and a semiconductor substrate. As a specific example, the substrate could be a substrate having small feature size. As another specific example, the substrate can be an advance logic chip. The method as described herein is particularly useful in planarizing such substrates without creating substantial undesirable dishing on the substrate being polished.

Preferably, the method of polishing a substrate of the present invention, comprises: providing a substrate selected from at least one of a magnetic substrate, an optical substrate and a semiconductor substrate (preferably a semiconductor substrate, such as a semiconductor wafer); providing a chemical mechanical polishing pad as disclosed herein; providing a polishing solution between the polishing pad and the substrate; creating dynamic contact between a polishing surface of the polishing layer and the substrate to polish a surface of the substrate; and, conditioning of the polishing surface with an abrasive conditioner during one or more intermittent breaks in the polishing.

As shown in FIG. 4, a substrate 10 to be polished incudes elevated features 11. A polishing pad 30, having polymeric beads 31 in a matrix polymer 22 does not substantially deform into the region between the elevated features 11 under the pressure of polishing.

### EXAMPLES

### Example Set 1

Polishing pads were made with the same polyurethane matrix polymer and varying non-reactive additives as shown in Table 1. They were used to polish a substrate and evaluated for dishing. A set of CVD oxide patterned SKW 3-2 300 mm wafers from SKW Associates, Inc. were used for the polishing. The top oxide surface was removed by polishing and stop on the Si3N4 layer, then the lost height of trench oxide was measured by Brucker Atomic Force Microscopy (AFM) at 6 locations of different feature sizes that are 500 μm×500 μm, 250 μm×250 μm, 100 μm×100 μm, 50 μm×50 μm, (in trench width and land width), 30% density (30 μm high area/70 μm low area), and 70% density (70 μm high area/30 μm low area). An over polishing of 15% beyond end point detection was used. In addition, pads made with polishing layers 1, A, B and C were evaluated for defectivity looking for chattermarks at high downforce (HDF, 170 hectoPascals) and low downforce (LDF, 120 hectoPascals) based on stress exerted on the entire surface area of the polished substrate what area. The pads were conditioned ex situ (i.e., during pauses in the polishing of the substrates). The results are shown in Table 1.

### Example Set 2

A second set of polishing pads were made with the same polyurethane matrix polymer as in Example Set 1 and varying non-reactive additives as shown in Table 2 and used to polish as in Example Set 1 except the polish was continued to 30% over polish after endpoint detection. With this additional over-polish the dishing was more severe. However, samples 1-2 with the PMMA beads still had lower dishing than Comparative Sample A having expandable polymeric microspheres. While comparative Sample D showed reasonably good dishing results, the sample was not able to be machined without extreme defects as shown in FIG. 11.

### Example Set 3

A third set of polishing pads were made with the same polyurethane matrix polymer as in Example Set 1 and varying non-reactive additives as shown in Table 3. Note that “7/3” indicates 7 micron line width with 3 micron space width. These were used to polish 8 inch (20.3 cm) tungsten patterned wafers. Results are as shown in Table 3.

TABLE 1

| | | Amount of | | | | | | | | | |
|---|---|---|---|---|---|---|---|---|---|---|---|
| | | Additives | | | | | | | | | |
| | | (wt % | | | | | | | | | |
| | | based on | Density of | | | | | | | | |
| | | total weight | Polishing | | | | | | | | |
| Sample | | of polishing | Layer | Dishing performance (Angstroms) | | | | | | Chattermarks | |
| ID | Type of Additives | layer) | (g/cc) | 500 × 500 | 250 × 250 | 100 × 100 | 50 × 50 | 30% | 70% | HDF | LDF |
| A | Expancel ™ expandable | 1% | 1.01 | 218 | 194 | 139 | 118 | 309 | 37 | 91-127 | 76-90 |
| | polymeric microspheres | | | | | | | | | | |
| 1 | Crosslinked | 10% | 1.13 | 169 | 176 | 133 | 106 | 295 | 10 | 73-75 | 85-93 |
| | polymethylmethacrylate | | | | | | | | | | |
| | beads with avg size 11- | | | | | | | | | | |
| | 12 microns (“PMMA | | | | | | | | | | |
| | beads”) | | | | | | | | | | |
| B | PMMA beads and | 10% and | 0.79 | 431 | 382 | 259 | 230 | 426 | 73 | 168-255 | 192-213 |
| | Expancel ™ expandable | 3% | | | | | | | | | |
| | polymeric microspheres | respectively | | | | | | | | | |
| C | Polytetrafluorethylene | 7.5% and | 1.05 | 244 | 222 | 139 | 125 | 344 | 40 | 74-135 | 75-82 |
| | particles (avg particle | 1% | | | | | | | | | |
| | size 3 microns) and | respectively | | | | | | | | | |
| | Expancel ™ expandable | | | | | | | | | | |
| | polymeric microspheres | | | | | | | | | | |

* Polytetrafluoroethylene particles do not separate from the matrix upon casting and microtoming the polishing pad.

TABLE 2

| | | Amount of | | | | | | | | | |
|---|---|---|---|---|---|---|---|---|---|---|---|
| | | Additives | | | | | | | | | |
| | | (wt % | | | | | | | | | |
| | | based on | | | | | | | | | |
| | | total weight | Density of | | | | | | | | |
| | | of | Polishing | | | | | | | | |
| Sample | | polishing | Layer | Dishing performance (Angstroms) | | | | | | Chattermarks | |
| ID | Type of Additives | layer) | (g/cc) | 500 × 500 | 250 × 250 | 100 × 100 | 50 × 50 | 30% | 70% | HDF | LDF |
| A | Expancel ™ expandable | 1% | 1.01 | 1180 | 986 | 728 | 562 | 812 | 417 | 4-12 | 5-11 |
| | polymeric microspheres | | | | | | | | | | |
| D | Polytetrafluorethylene | 7.5% | 1.24 | 1007 | 778 | 468 | 310 | 526 | 221 | 5-18 | 2-6 |
| | particles (avg particle | | | | | | | | | | |
| | size 3 microns) | | | | | | | | | | |
| 1 | PMMA beads | 10% | 1.13 | 1103 | 896 | 653 | 492 | 678 | 357 | 13-22 | 13-24 |
| 2 | PMMA beads | 5% | 1.16 | 1015 | 814 | 574 | 429 | 625 | 323 | 5-15 | 7-10 |

TABLE 3

| | | Amount of Additives | | | | | | |
|---|---|---|---|---|---|---|---|---|
| | | (wt % based on total | Density of | | | | | |
| Sample | | weight of polishing | Polishing Layer | Dishing performance (Angstroms) | | | | W Removal Rate |
| ID | Type of Additives | layer) | (g/cc) | 100 × 100 | 10 × 10 | 0.25 × 0.25 | 7/3 | (Angstroms/min) |
| A | Expancel ™ | 1% | 1.01 | 1347 | 616 | 150 | 329 | 1196 |
| | expandable polymeric | | | | | | | |
| | microspheres | | | | | | | |
| 1 | PMMA beads | 10% | 1.13 | 1190 | 551 | 160 | 319 | 1297 |
| 3 | PMMA beads | 15% | 1.10 | 1213 | 513 | 156 | 294 | 1434 |

Tables 1 to 3 combine to illustrate that the PMMA polymeric beads provide equivalent or improved dishing, equivalent or improved defectivity all with improved tungsten removal rate. Expandable polymeric microspheres at 3 wt % increase chattermarks in relation to the PMMA polymeric beads of the invention.

This disclosure further encompasses the following aspects.

Aspect 1. A chemical mechanical polishing pad having a polishing layer, wherein the polishing layer comprises a matrix polymer and 1 to 20 wt % based on total weight of the polishing layer of non-reactive, non-expandable polymeric particles dispersed in the matrix polymer and less than 2 wt % expandable polymeric microspheres, wherein an SEM of a cut surface of the polishing layer shows a crescent shaped opening adjacent to at least a portion of the polymer particles and separating a surface of that portion of the polymer particles from the matrix polymer.

Aspect 2. The chemical mechanical polishing pad of Aspect 1 wherein the non-reactive, non-expandable polymeric particles comprise cross-linked polymethylmethacrylate.

Aspect 3. The chemical mechanical polishing pad of Aspect 1 or 2 wherein the non-reactive, non-expandable polymeric particles have an average particle size D50 particle size of 5 to 15 microns.

Aspect 4. The chemical mechanical polishing pad of any of the previous Aspects wherein the matrix polymer is ductile.

Aspect 5. The chemical mechanical polishing pad of any of the previous Aspects wherein the matrix polymer is a polyurethane comprising the reaction product an isocyanate terminated prepolymer and an amine curative wherein the isocyanate terminated prepolymer comprises a reaction product of a polyol prepolymer, toluene diisocyanate, a low molecular weight polyol wherein the reaction product is further reacted with an amine curative.

Aspect 6. The chemical mechanical polishing pad of any of the previous Aspects wherein the isocyanate prepolymer comprises a blend of a first reaction product of a polypropylene glycol, toluene diisocyanate and the low molecular weight polyol and a second reaction product of a polytetramethylene glycol, toluene diisocyanate and the low molecular weight polyol, wherein the first reaction product and the second reaction product are present in a weight ratio of 1:20 to 1:1.

Aspect 7. The chemical mechanical polishing pad of any of the previous Aspects having a density of at least 1.1 grams per cubic centimeter.

Aspect 8. The chemical mechanical polishing pad of any of the previous Aspects further including grooves on the surface of the polishing layer.

Aspect 9. The chemical mechanical polishing pad of Aspect 8 wherein the grooves are machined into the surface of the polishing layer.

Aspect 10. The chemical mechanical polishing pad of any of the previous Aspects wherein the non-reactive, non-expandable polymeric particles are porous.

All ranges disclosed herein are inclusive of the endpoints, and the endpoints are independently combinable with each other (e.g., ranges of “up to 25 wt %, or, more specifically, 5 wt % to 20 wt %”, is inclusive of the endpoints and all intermediate values of the ranges of “5 wt % to 25 wt %,” etc.). Moreover, stated upper and lower limits can be combined to form ranges (e.g. “at least 1 or at least 2 wt %” and “up to 10 or 5 wt %” can be combined as the ranges “1 to 10 wt %”, or “1 to 5 wt %” or “2 to 10 wt %” or “2 to 5 wt %”).

The disclosure may alternately comprise, consist of, or consist essentially of, any appropriate components herein disclosed. The disclosure may additionally, or alternatively, be formulated so as to be devoid, or substantially free, of any components, materials, ingredients, adjuvants or species used in the prior art compositions or that are otherwise not necessary to the achievement of the function and objectives of the present disclosure.

All cited patents, patent applications, and other references are incorporated herein by reference in their entirety. However, if a term in the present application contradicts or conflicts with a term in the incorporated reference, the term from the present application takes precedence over the conflicting term from the incorporated reference.

Unless specified to the contrary herein, all test standards are the most recent standard in effect as of the filing date of this application, or, if priority is claimed, the filing date of the earliest priority application in which the test standard appears.

What is claimed is:

1. A chemical mechanical polishing pad having a polishing layer, wherein the polishing layer comprises a matrix polymer and 1 to 20 wt % based on total weight of the polishing layer of non-reactive, non-expandable polymeric particles dispersed in the matrix polymer and less than 2 wt % expandable polymeric microspheres, wherein an SEM of a cut surface of the polishing layer shows a crescent shaped opening adjacent to at least a portion of the polymer particles and separating a surface of that portion of the polymer particles from the matrix polymer.

2. The chemical mechanical polishing pad of claim 1 wherein the non-reactive, non-expandable polymeric particles comprise cross-linked polymethylmethacrylate.

3. The chemical mechanical polishing pad of claim 1 wherein the non-reactive, non-expandable polymeric particles have an average particle size D50 particle size of 5 to 15 microns.

4. The chemical mechanical polishing pad of claim 1 wherein the matrix polymer is ductile.

5. The chemical mechanical polishing pad of claim 1 wherein the matrix polymer is a polyurethane comprising the reaction product an isocyanate terminated prepolymer and an amine curative wherein the isocyanate terminated prepolymer comprises a reaction product of a polyol prepolymer, toluene diisocyanate, a low molecular weight polyol wherein the reaction product is further reacted with an amine curative.

6. The chemical mechanical polishing pad of claim 5 wherein the isocyanate prepolymer comprises a blend of a first reaction product of a polypropylene glycol, toluene diisocyanate and the low molecular weight polyol and a second reaction product of a polytetramethylene glycol, toluene diisocyanate and the low molecular weight polyol, wherein the first reaction product and the second reaction product are present in a weight ratio of 1:20 to 1:1.

7. The chemical mechanical polishing pad of claim 1 having a density of at least 1.1 grams per cubic centimeter.

8. The chemical mechanical polishing pad of claim 1 further including grooves on the surface of the polishing layer.

9. The chemical mechanical polishing pad of claim 8 wherein the grooves are machined into the surface of the polishing layer.

10. The chemical mechanical polishing pad of claim 1 wherein the non-reactive, non-expandable polymeric particles are porous.
